(19) United States
(12) Patent Application Publication
(10) Pub. No.: US 2010/0001355 A1
(43) Pub. Date: Jan. 7, 2010

(54) RF MEMS Switch

(75) Inventors: Andrzej Peczalski, Eden Prairie, MN (US); James F. Detry, Plymouth, MN (US); Paul E. Bauhahn, Fridley, MN (US); Nicol McGruer, Boston, MA (US)

Correspondence Address: HONEYWELL INTERNATIONAL INC.;PATENT SERVICES, 101 COLUMBIA ROAD, P O BOX 2245, MORRISTOWN, NJ, 07962-2245, US

(73) Assignees: HONEYWELL INTERNATIONAL INC., Morristown, NJ (US); NORTHEASTERN

(21) Appl. No.: 12/168,647

(22) Filed: Jul. 7, 2008

(51) Int. Cl. B81B 3/00; H01L 21/62

(52) U.S. Cl. 257/415; 438/52

(57) ABSTRACT

An RF MEMS switch having a beam composed of a material having a high resistivity and a large Young's modulus may provide a large restoring force, a large electrostatic force at a low actuation voltage, and good isolation between signal input and output. RF MEMS switch reliability may be improved by reducing failures due to stiction by providing a large restoring force. A reliable contact may be provided with a large electrostatic force.

### GOVERNMENT RIGHTS

The United States Government may have acquired certain rights in this invention pursuant to Contract No. W911QX-06-C-0097 awarded by DARPA.

### FIELD OF THE INVENTION

The present invention relates generally to a radio frequency (“RF”) MEMS circuit and method of fabricating an RF MEMS circuit. More particularly, the invention relates to a circuit and method of fabricating an RF MEMS circuit having a large restoring force and a small contact area.

### BACKGROUND

RF MEMS switches may be used for switchable signal routing and time-delay phase-shifter networks, among other applications. An RF MEMS switch may be electrically configured in series or in parallel with a radio frequency transmission line. The device may be designed to switch the transmission line on or off when the RF MEMS device is activated.

RF MEMS switches may have a beam having a contact. The beam may have one leg or several legs supporting the beam. When the beam experiences deflection, a supporting force from the beam legs and the tendency of the beam to return to its original position before it was deflected may provide a restoring spring force to restore the beam to its neutral position.

RF MEMS switches may also have RF contacts located near a signal line. When an RF MEMS switch is activated by applying an actuation voltage between the beam and the RF grounds, an electrostatic force may be created between the beam and the RF grounds. The electrostatic force may pull the beam toward the RF grounds, causing the contact on the beam to come into contact with a contact on the signal line. Thus, the signal line may be switched on or off by applying an actuation voltage to an RF MEMS switch.

For good switching performance, it may be important that the signal line contact and the contact on the beam have good contact force between them. This may be accomplished by providing a large electrostatic force to pull the beam toward the signal line contact and to provide a force to hold the beam contact against the signal line contact.

The nature of the contact or impurities or foreign particles between the contacts may cause the beam contact to stick to the signal line contact, a problem known as stiction. Stiction may negatively affect the reliability of the switching device. If the beam contact sticks to the signal line contact, and the restoring spring force is insufficient to restore the beam to its unactivated position, the switch will be stuck in an activated position even when the activation voltage is removed.

One way to counteract problems with stiction is to provide a large restoring force from the beam and the beam legs. However, the beam may cause interference with the RF signal. Therefore, in order to minimize problems with RF interference it may be problematic to implement a large beam and beam legs.

Therefore, an improved method of providing reliable contact and a large restoring force for RF MEMS switches is needed.

### SUMMARY

An RF MEMS switch and a method of fabricating an RF MEMS switch having a large restoring force, a small contact area, and low RF interference is described. The RF MEMS switch has a large beam and beam legs that may provide a large restoring force to pull the switch open when an activation voltage is removed. The beam and beam legs may be composed of a material having a high resistivity and a large Young's modulus, such as polysilicon, some crystalline and polycrystalline carbonates, nitrides, and diamonds (e.g., SiC, AlN). The high resistivity of the beam material may provide minimal interference with the RF signal passing through the switch. Because of the high resistivity of the beam material, the beam and beam legs may be large and in close proximity to the RF signal lines and may still provide minimal interference with the RF signals passing through the RF MEMS switch.

By increasing the surface area of the beam, the actuation voltage may be reduced to achieve a given electrostatic force. A large electrostatic force may also enable the distance between the beam and the substrate to be increased, which may provide improved electrical isolation. When the beam is supported on opposite sides by beam legs, placing the contact(s) near the center of the beam may also increase the contact force achieved for a given beam surface area.

Stiction between the beam contact and the signal line contact may occur due to contaminants or other particles in contact with the beam contact or signal line contact. A metal contact may be provided on the beam. The metal contact may have a small raised contact area. A small raised contact area may minimize stiction by reducing the area of contact between the beam contact and the signal line contact. Because the raised contact area may be small relative to the beam, the electrostatic force and restoring force may be large, while stiction may be minimized.

Thus, an RF MEMS switch having a beam and beam legs composed of a material having a high resistivity and a large Young's modulus may reduce switch reliability problems due to stiction, while maintaining a large contact and restoring force to provide good contact between the beam contact and the signal line contact.

These as well as other aspects and advantages will become apparent to those of ordinary skill in the art by reading the following detailed description, with reference where appropriate to the accompanying drawings. Further, it is understood that this summary is merely an example and is not intended to limit the scope of the invention as claimed.

### BRIEF DESCRIPTION OF THE DRAWINGS

Presently preferred embodiments are described below in conjunction with the appended drawing figures, wherein like reference numerals refer to like elements in the various figures, and wherein:

FIG. 1a is a top view of an RF MEMS switch, according to an embodiment.

FIG. 1b is a top view of an RF MEMS switch, according to an embodiment.

FIG. 2a is a cutaway view of an RF MEMS switch in fabrication, according to an embodiment.

FIG. 2b is a cutaway view of an RF MEMS switch in fabrication, according to an embodiment.

FIG. 2c is a cutaway view of an RF MEMS switch in fabrication, according to an embodiment.

FIG. 2d is a cutaway view of an RF MEMS switch in fabrication, according to an embodiment.

FIG. 2e is a cutaway view of an RF MEMS switch in fabrication, according to an embodiment.

FIG. 2f is a cutaway view of an RF MEMS switch in fabrication, according to an embodiment.

FIG. 2g is a cutaway view of an RF MEMS switch in fabrication, according to an embodiment.

FIG. 2h is a cutaway view of an RF MEMS switch in fabrication, according to an embodiment.

FIG. 2i is a cutaway view of an RF MEMS switch in fabrication, according to an embodiment.

FIG. 2j is a cutaway view of an RF MEMS switch in fabrication, according to an embodiment.

FIG. 2k is a cutaway view of an RF MEMS switch, according to an embodiment.

FIG. 2l is a cutaway view of an RF MEMS switch, according to an embodiment.

FIG. 3a is a cutaway view of an RF MEMS switch in fabrication, according to an embodiment.

FIG. 3b is a cutaway view of an RF MEMS switch in fabrication, according to an embodiment.

FIG. 3c is a cutaway view of an RF MEMS switch, according to an embodiment.

FIG. 3d is a cutaway view of an RF MEMS switch, according to an embodiment.

### DETAILED DESCRIPTION

An RF MEMS switch and a method of fabricating an RF MEMS switch that may provide improved reliability and improved resistance to stiction is described.

An RF MEMS switch may have a signal line with a signal line contact area and a beam supported by at least one beam leg having a beam contact area. When an actuation voltage is applied between the beam and actuation contacts located on the substrate, an electrostatic force may pull the beam downward. The beam contact may make electrical contact with the signal line contact.

A beam and beam legs may be composed of a material having a high resistivity. For example, a material having a resistivity of at least at least 1000 Ω-cm would provide desirably low levels of RF interference. A high resistivity may provide reduced interference with RF signals passing through or disconnected by the RF MEMS switch. Because the interference with RF signals may be reduced, the size of the beam and beam legs may be increased without providing unacceptable levels of RF interference. A large beam and beam legs may provide a large restoring force to open the switch when the actuation voltage is removed. For example, the beam legs may have a thickness equal to or greater than the thickness of the beam. For a beam and beam legs composed of high resistivity polysilicon, the thicknesses may be greater than 4.0 μm.

Examples a high resistivity material which may be used to compose the beam and beam legs are polysilicon, some crystalline and polycrystalline carbonates, nitrides, and diamonds (e.g., SiC, AlN). These materials may also have a large Young's modulus, i.e. greater than 150 GPa, which may provide a large restoring force to restore the beam when the RF MEMS switch is in an unactivated state.

Additionally, a large surface area of the beam may provide an increased electrostatic force for a given actuation voltage. For example, a beam having a surface area of approximately 1-8×10⁻⁸ m² may provide low actuation voltages of approximately 18-40V. For example, beam legs having lengths of approximately 40-60 μm and a thickness of 4-8 μm may provide a restoring force of approximately 350-630 μN. Therefore, large electrostatic forces may be produced while maintaining low actuation voltages.

In some cases, the resistivity of the beam may cause the conductivity to be so low that the actuation voltage may not be sufficient to provide enough electrostatic force to pull down the beam. If this is the case, a thin layer of a highly conductive metal, such as platinum, may be deposited on the top of the beam. This may increase the conductivity of the beam as a whole and may allow accurate beam response to the actuation voltage. The highly conductive metal may be any highly conductive metal known in the art. Methods of depositing metal layers are well known in the art and not described herein.

Further, a large electrical permittivity may provide an increased electrostatic force for a given actuation voltage for a polysilicon beam having a metal layer deposited on top of the beam. For example, polysilicon may have a relative permittivity of approximately 11.9.

Further, a metal contact located on the beam may come into electrical contact with a signal line contact located on the RF MEMS switch. The metal contact on the beam may have a raised profile that forms a contact bumps or contact bumps. The contact bump may come into physical contact with the signal line when the switch is activated. The contact bumps may be approximately 0.2%-1% of the beam surface area. The small contact area between the beam and the signal line contact and the large restoring force may reduce the possibility of failure due to stiction. Further, the distance between the beam and the substrate may be increased because of the large electrostatic force. For example, the beam may be located approximately 2 μm above the signal line contact. The increased distance between the beam and the signal line contact may provide improved electrical isolation when the switch is in an open state. For example, the isolation of an open switch of the present invention may have isolation values of approximately 30 dB.

Thus, an RF MEMS switch having a beam and beam legs composed of a material having a high resistivity and a large Young's modulus may reduce switch reliability problems due to stiction by applying a large restoring force, while maintaining a large contact force to provide good contact between the contact bump and the signal line contact.

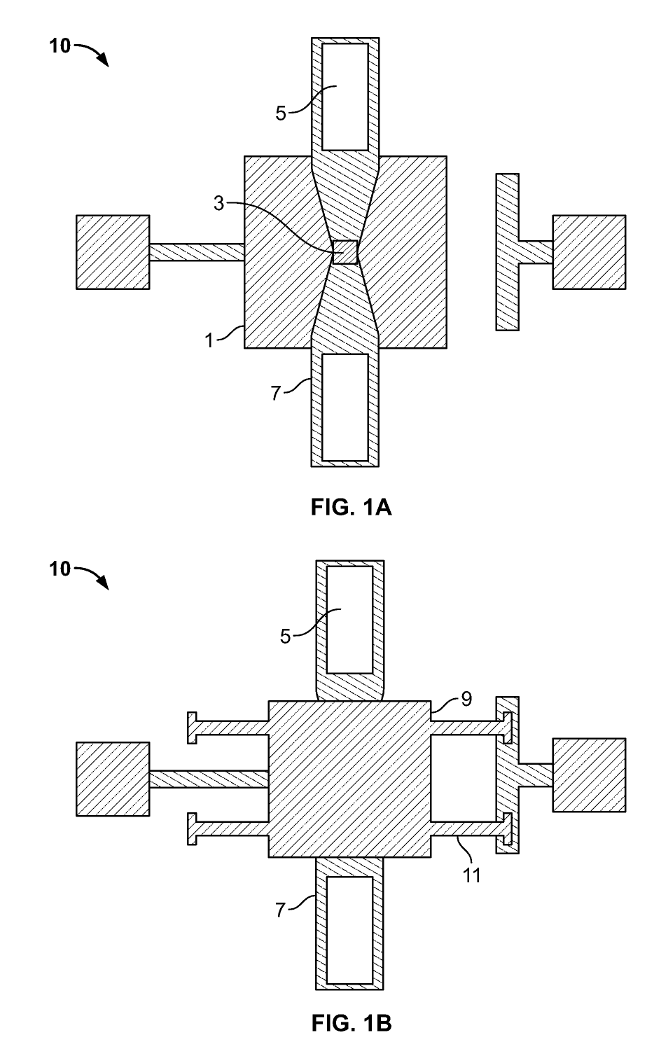

FIG. 1a shows a top view of a base level of an RF MEMS switch 10. The RF MEMS switch 10 may have an actuation contact 1, a signal line contact 3, signal electrodes 5, and signal line 7. The signal line contact 3 may come into electrical contact with a contact on a beam, discussed further with respect to FIG. 1b. The RF MEMS switch 10 may achieve an “on” position when the beam contact electrically contacts the signal line contact 3, and an RF signal may pass through an electric path between the beam and the signal line 7. The signal electrodes 5 may be located on the signal line 7. The signal electrodes 5 may be contacted to receive the RF signal conducted by the signal line 7.

An actuation voltage may be applied across actuation contacts 1. The actuation voltage may create a voltage differential between the beam and the actuation contacts 1, creating an electrostatic force between the actuation contact 1 and the beam, discussed further with respect to FIG. 1b. The amount of electrostatic force is proportional to the area of the beam and the actuation contacts, the electric permittivity of electrically insulating areas located between the beam and the actuation contacts 1, and the square of the actuation voltage applied, and is inversely proportional to the square of the vertical distance between the beam and the signal line contact 3. Therefore, a material having a large surface area may have a large electrostatic force for a given actuation voltage.

FIG. 1b shows the RF MEMS switch 10 with the beam 9 and the beam legs 11. The RF MEMS switch 10 shown has four beam legs 11; however, other numbers of beam legs 11 may be used. The beam 9 may be supported by the beam legs 11. When the beam 9 is deflected by the electrostatic force created by the actuation voltage, the beam legs 11 may provide a restoring force to the beam 9 to return the beam 9 to its “off” position.

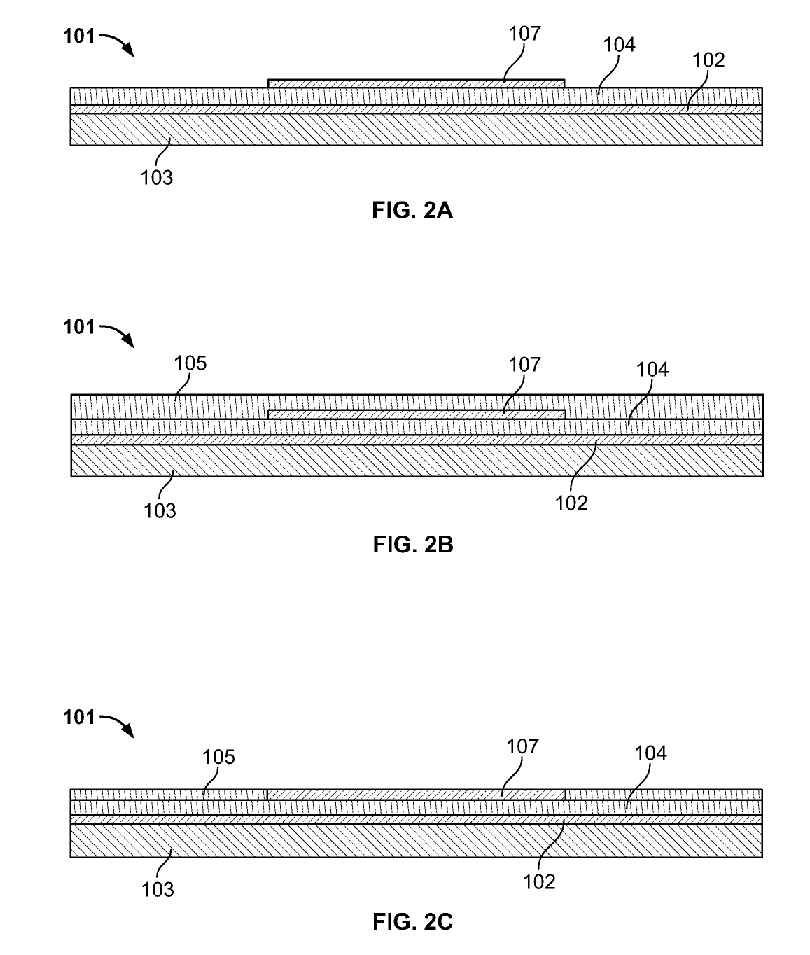

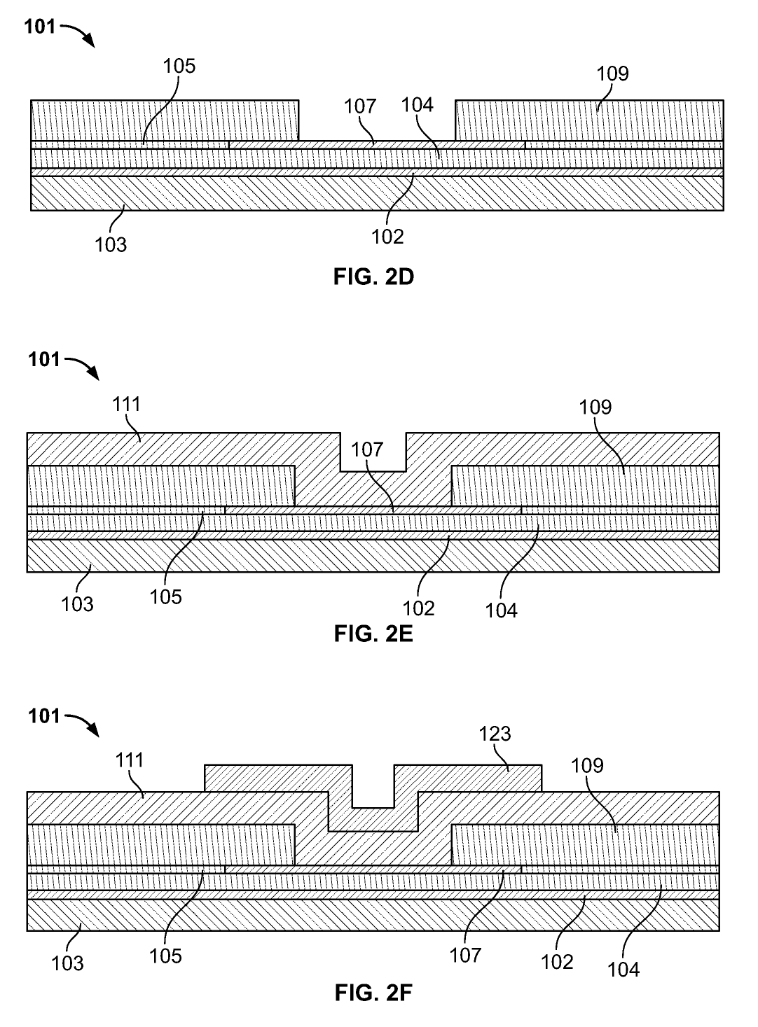

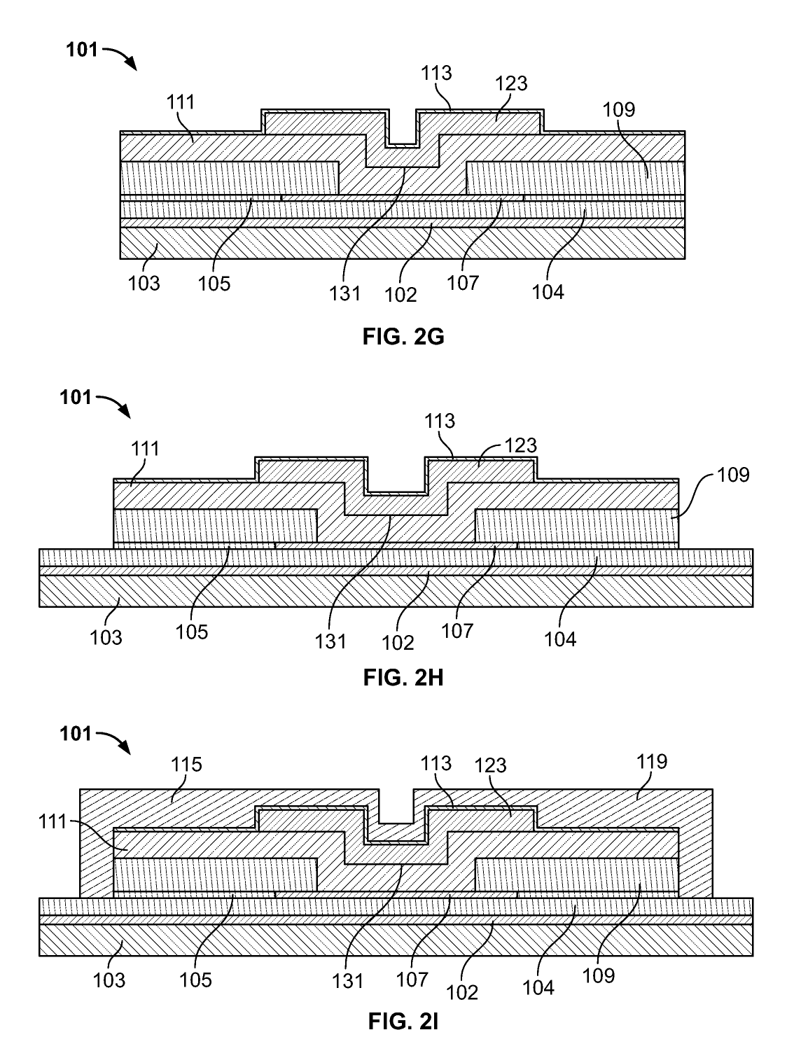

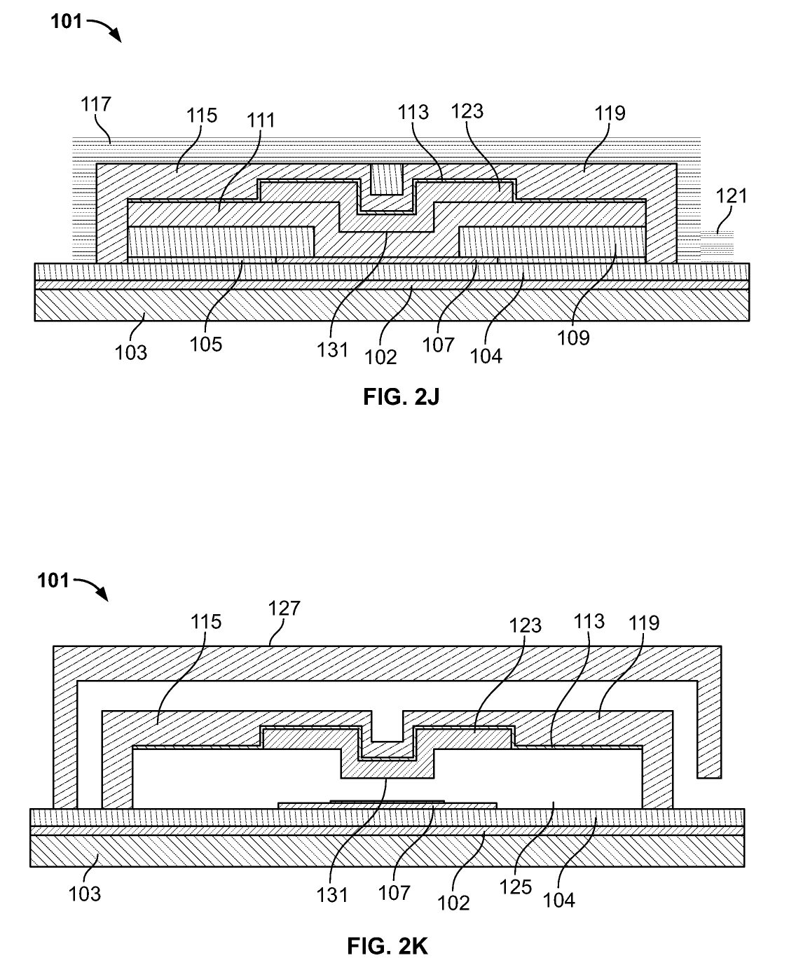

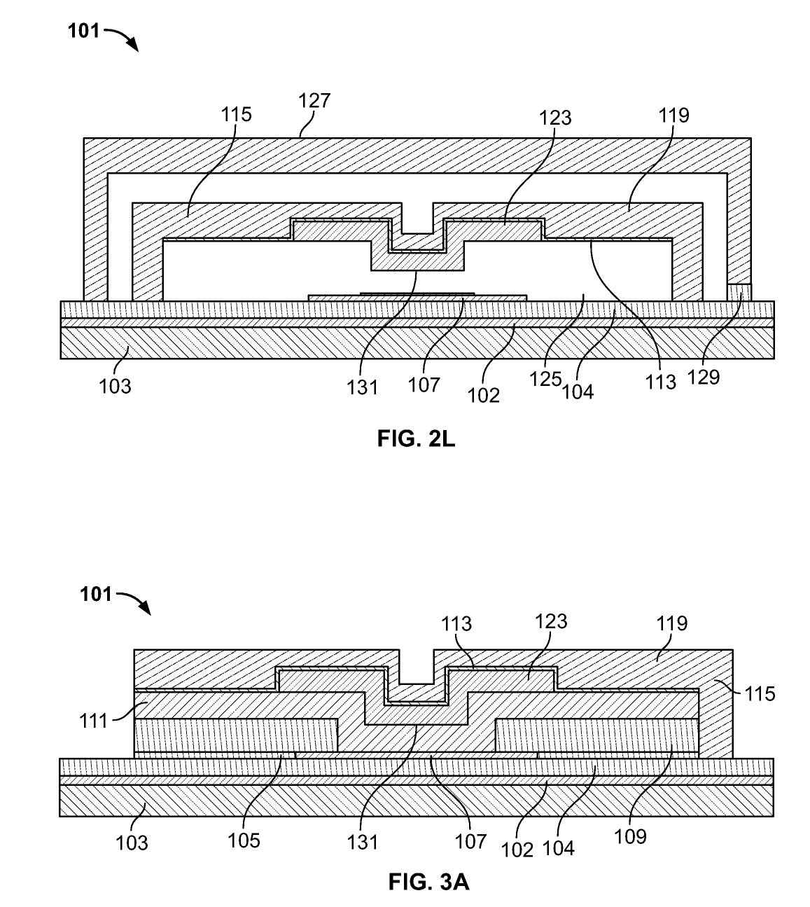

FIGS. 2a-2l are side views showing a method of manufacturing an RF MEMS switch 101. Referring to FIG. 2a, a substrate 103 is provided. Any substrate material known in the art may be used. Glass or ceramic substrates may have beneficial properties in that a glass or ceramic substrate 103 may cause less conductive loss through the substrate 103 than other known silicon substrates. Actuation electrodes are located on the substrate 103.

An actuation electrode 102 may be deposited on the substrate 103. Methods of patterning and depositing actuation electrodes are well known in the art and are not described in detail herein. An isolation layer 104 may be deposited over the actuation electrode 102. The isolation layer may be silicon nitride, for example.

A first metal contact 107 may be deposited on the substrate. The first metal layer 107 may be any metal known in the art that may be deposited on a substrate. The first metal contact 107 may be patterned to have the desired profile, for example, by using a photolithography and wet or dry etch. Methods of patterning and etching materials in the manufacture of integrated circuits are well known in the art and not described in detail herein.

Referring to FIG. 2b, a first sacrificial layer 105 may be deposited. The first sacrificial layer 105 may be silicon dioxide, for example.

Referring to FIG. 2c, the first sacrificial layer 105 and the first metal contact 107 may be planarized to have a flat profile.

Referring to FIG. 2d, a second sacrificial layer 109 may be deposited and patterned. The second sacrificial layer 109 may be silicon dioxide, for example. The second sacrificial layer 109 may be patterned to have a gap that exposes the first metal contact 107.

Referring to FIG. 2e, a third sacrificial layer 111 may be deposited.

Referring to FIG. 2f, the indentation formed in the third sacrificial layer 111 due to the gap in the second sacrificial layer 109 may provide a space for a second metal contact 123 having a raised profile, as shown in FIG. 2f. The raised profile of the second metal contact 123 forms a contact bump 131. The small surface area of the contact bump 131 compared to the second metal contact 123 provides a small contact area between the first metal contact 107 and the second metal contact 123, resulting in the advantages discussed above.

Referring to FIG. 2g, an isolation layer 113 may be deposited over the third sacrificial layer and the second metal contact 123. The isolation layer 113 may electrically and physically isolate the second metal contact 123 from the beam, discussed further with respect to FIG. 2i. The isolation layer 113 may be any dielectric substance known in the art that may insulate layers from electrical contract with each other.

Referring to FIG. 2h, the first, second, and third sacrificial layers 105, 109, 111 and the isolation layer 113, if present, may be patterned to provide areas 300 on the substrate for the beam legs, discussed further with respect to FIG. 2i.

Referring to FIG. 2i, a layer of polysilicon may be deposited and patterned to form a beam horizontal portion 119 and beam vertical portion 115. The beam vertical portion 115 may be solid. Alternatively, there may be multiple beam vertical portions 115 on multiple sides or on corners of the beam horizontal portion 119, as shown in FIG. 1b.

Referring to FIG. 2j, a fourth sacrificial layer 117 may be deposited and patterned. A sacrificial removal channel 121 may also be deposited, to provide an area to apply the etch to remove the sacrificial layers 105, 109, 111, 117 when the package layer, discussed further with respect to FIG. 2k, may be deposited over the fourth sacrificial layer 117. The sacrificial removal channel 121 is shown in FIG. 2j as having a similar thickness at the fourth sacrificial layer 117; however the sacrificial removal channel 121 may be any thickness and may preferably be smaller than the fourth sacrificial layer 117.

Referring to FIG. 2k, a package layer 127 is deposited over the fourth sacrificial layer 117. The package layer 127 may be any material used in packaging integrated circuits. The sacrificial layers 105, 109, 111, 117 may be removed with an etch. The gap 125 between the beam horizontal portion 119 and the first metal contact 107 may be filled with air or another gas, and may be a vacuum. The space remaining between the package 127 and the substrate 103 may be sealed after the sacrificial layers 105, 109, 111, 117 are removed, described further with respect to FIG. 2l. The package 127 may protect the RF MEMS switch 101 from unwanted contaminants, for example.

Referring to FIG. 2l, the sacrificial removal channel 121 may be sealed by depositing a material 129 to seal the sacrificial removal channel 121. The material 129 may be the material used for the package layer 127, or, alternatively, may be any material known in the art used to package integrated circuits.

The RF MEMS switch has a space between the first metal contact 107 and the contact bump 131. When the actuation voltage is applied to the RM MEMS switch 101, the beam horizontal portion 119 is drawn toward the substrate 103, placing the first metal contacts 107 and the contact bump 131 in electrical contact. The beam vertical portion 115 supports the beam horizontal portion 119 and provides a restoring force when the beam horizontal portion 119 is deflected.

The thickness of the third sacrificial layers 111 may be designed to create a predetermined distance between the bottom surface of the contact bump 131 and the first metal contact 107. The total thicknesses of the second and third sacrificial layers 109, 111 may be determined to create a predetermined distance between the bottom surface of the beam horizontal portion 119 and the first metal contact 107. These distances may be designed to optimize the contact force between the contact bump 131 and the first metal layer 107 and the restoring force from the beam vertical portion 115.

In another example, the beam horizontal portion 119 may have a cantilever configuration, supported on one side by at least one beam vertical portion 115. The RF MEMS switch 101 may be fabricated as described with respect to FIGS. 2a-h.

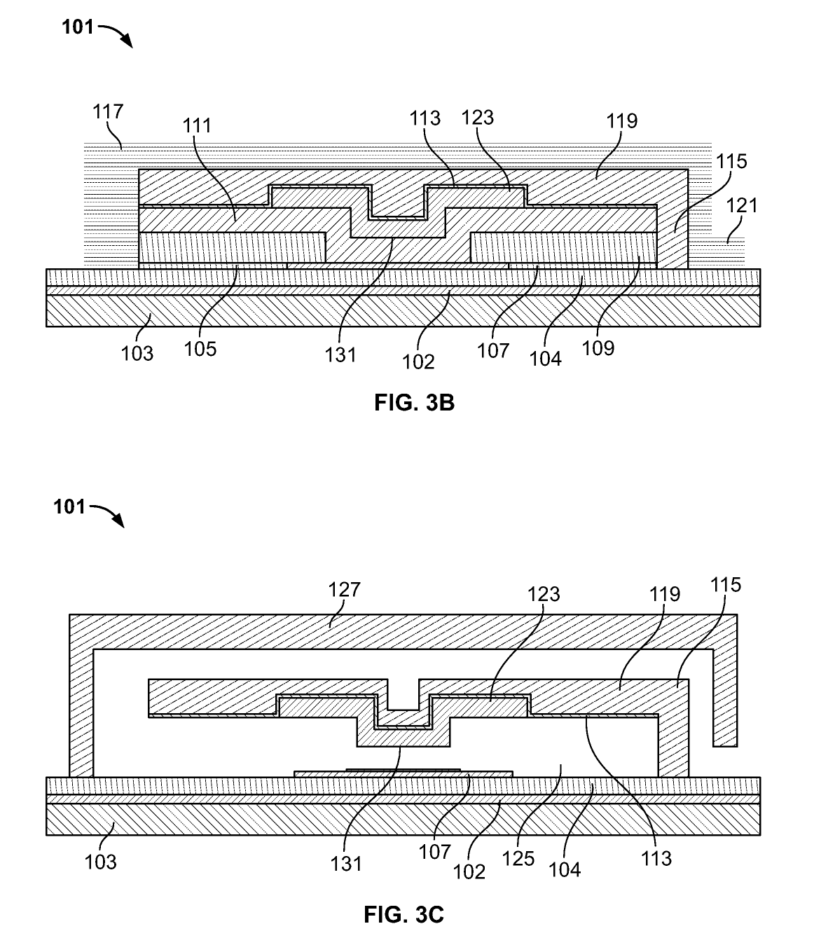

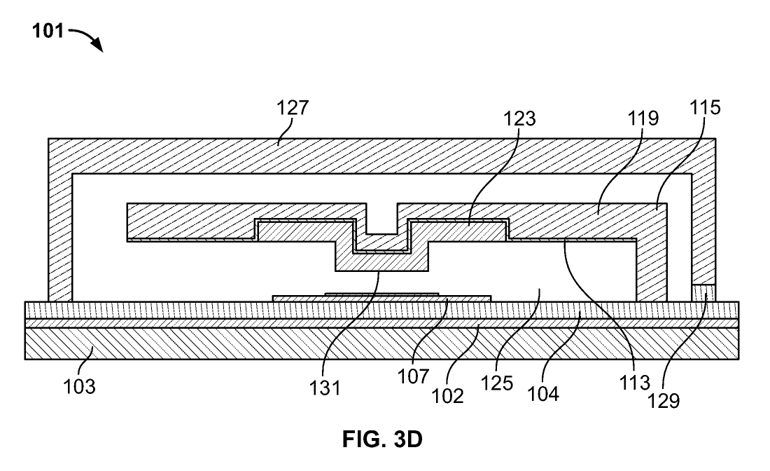

Referring to FIG. 3a, a layer of polysilicon may be deposited and patterned to form a beam horizontal portion 119 and at least one beam vertical portion 115. The beam vertical portion 115 may be solid. Alternatively, there may be multiple beam vertical portions 115 supporting the beam horizontal portion 119.

Referring to FIG. 3b, a fourth sacrificial layer 117 may be deposited and patterned. A sacrificial removal channel 121 may be deposited. The sacrificial removal channel 121 is shown in FIG. 2j as having a similar thickness at the fourth sacrificial layer 117; however the sacrificial removal channel 121 may be any thickness and may preferably be smaller than the fourth sacrificial layer 117.

Referring to FIG. 3c, a package layer 127 is deposited over the fourth sacrificial layer 117. The package layer 127 may be any material used in packaging integrated circuits. An etch may be applied across the sacrificial removal channel 121 to remove the sacrificial layers 105, 109. 111, 117. The gap 125 between the beam horizontal portion 119 and the first metal contact 107 may be filled with air or another gas, and may be a vacuum.

Referring to FIG. 3d, the sacrificial removal channel 121 may be sealed by depositing a material 129 to fill the sacrificial removal channel 121. The material 129 may be the material used for the package layer 127, or, alternatively, may be any material known in the art used to package integrated circuits.

It should be understood that the illustrated embodiments are examples only and should not be taken as limiting the scope of the present invention. The claims should not be read as limited to the described order or elements unless stated to that effect. Therefore, all embodiments that come within the scope and spirit of the following claims and equivalents thereto are claimed as the invention.

We claim:

1. A method of producing an RF MEMS switch, comprising:
providing a substrate, wherein the substrate comprises at least one actuation electrode;
depositing a first metal contact on the substrate, wherein the first metal contact is electrically connected to at least one signal line;
depositing at least one sacrificial layer;
depositing a second metal contact,
wherein the first and second metal contacts are separated by the at least one sacrificial layer, and
wherein the second metal contact has at least one contact bump;
depositing a beam,
wherein the beam contacts the second metal contact;
depositing at least one beam leg,
wherein the beam and the at least one beam leg comprise a material having a resistivity of at least 1000 Ω-cm, and
wherein the beam is in contact with at least one beam leg.

2. The method of claim 1, further comprising removing the at least one sacrificial layer.

3. The method of claim 1, wherein the material has a Young's modulus of at least 150 GPa.

4. The method of claim 1, wherein the at least one contact bump has a surface area smaller than the surface area of the beam.

5. The method of claim 1, further comprising depositing an isolation layer between the second metal contact and the beam, wherein the isolation layer is a dielectric.

6. The method of claim 1, wherein the at least one sacrificial layer comprises:
a first sacrificial layer,
wherein the first sacrificial layer is deposited over the first metal contact, and wherein the first sacrificial layer is planarized to expose at least a portion of the first metal contact;
a second sacrificial layer,
wherein the second sacrificial layer is deposited over the first sacrificial layer and the first metal contact, and wherein the second sacrificial layer is patterned and etched to expose at least a portion of the first metal contact;
a third sacrificial layer, wherein the third sacrificial layer is deposited over the second sacrificial layer and the first metal contact.

7. The method of claim 1, wherein the at least one sacrificial layer is silicon dioxide.

8. The method of claim 1, wherein the at least one beam leg further comprises:
at least one beam leg in contact with a first section on a perimeter of the beam, and
at least one beam leg in contact with a second section on the perimeter of the beam.

9. The method of claim 1, wherein the at least one beam leg is located on one side of the beam.

10. An RF MEMS switch, comprising:
a substrate;
at least one actuation electrode located on the substrate;
a first metal contact;
a second metal contact;
a beam,
wherein the second metal contact is located on the beam,
wherein the second metal contact has at least one contact bump, and
at least one beam leg,
wherein the beam and the at least one beam leg comprise a material having a resistivity of at least 1000 Ω-cm, and
wherein the at least one beam leg is in contact with the beam.

11. The RF MEMS switch of claim 10, wherein the surface area of the at least one contact bump is less than 1% of the surface area of the beam.

12. The RF MEMS switch of claim 10, further comprising an isolation layer on a surface of the beam that is in contact with the second metal contact, wherein the isolation layer is a dielectric.

13. The RF MEMS switch of claim 10, wherein the material has a Young's modulus of at least 150 GPa.

14. The RF MEMS switch of claim 13, wherein:
in response to an electrical potential difference between the beam and the at least one actuation electrode, an electrostatic force pulls the beam toward the at least one actuation electrode,
the electrostatic force pulls the beam toward the at least one actuation electrode so that the first metal contact is in electrical contact with the at least one contact bump; and
in response to a movement of the beam toward the at least one actuation electrode, the at least one beam leg exerts a restoring force on the beam, wherein the restoring force is at least partially in an opposite direction of the electrostatic force.

15. The RF MEMS switch of claim 10, wherein the at least one beam leg further comprises:
at least one beam leg in contact with a first section on the perimeter of the beam, and
at least one beam leg in contact with a second section on the perimeter of the beam.

16. The RF MEMS switch of claim 10, wherein the at least one beam leg is located on one side of the beam.

17. The RF MEMS switch of claim 10, further comprising a package layer located around the beam.

18. The RF MEMS switch of claim 17, wherein the package layer hermetically seals the RF MEMS switch.

19. An RF MEMS switch, comprising:
a substrate;
at least one actuation electrode located on the substrate;
a first metal contact;
a second metal contact, wherein the second metal contact has at least one contact bump;
a beam,
wherein the second metal contact is located on the beam;
at least one beam leg,
wherein the beam and the at least one beam leg comprise a material having a resistivity of at least 1000 Ω-cm and a Young's modulus of at least 150 GPa,
wherein the at least one beam leg is in contact with the beam, and
wherein a thickness of the at least one beam leg is equal to or greater than a thickness of the beam;
wherein, in a first condition, there is a space between the first metal contact and the second metal contact, wherein the first condition corresponds to no electrical potential difference between the beam and the at least one actuation electrode;
wherein, in a second condition, an electrostatic force pulls the beam toward the substrate, wherein the second condition corresponds to an electrical potential difference between the beam and the at least one actuation electrode;
wherein the electrostatic force pulls the beam toward the at least one actuation electrode so that the first metal contact is in electrical contact with the at least one contact bump;
wherein the at least one contact bump is smaller than the beam;
wherein, in response to the translation of the beam toward the at least one actuation electrode in response to the electrostatic force, the at least one beam leg exerts a restoring force on the beam; and
wherein the restoring force is at least partially in an opposite direction of the electrostatic force.

20. The RF MEMS switch of claim 19, wherein the at least one beam leg further comprises:
at least one beam leg in contact with a first side of the beam, and at least one beam leg in contact with a second side of the beam.
